(19) United States
(12) Patent Application Publication
(10) Pub. No.: US 2009/0009185 A1
(43) Pub. Date: Jan. 8, 2009

(54) Diagnostic System For Monitoring A Connector

(76) Inventor: Thomas Herbst, Alfeld (DE)

Correspondence Address: KENYON & KENYON LLP, ONE BROADWAY, NEW YORK, NY, 10004, US

(21) Appl. No.: 11/793,120

(22) PCT Filed: Nov. 18, 2005
(86) PCT No.: PCT/EP05/56061

§ 371 Date: Sep. 15, 2008

(30) Foreign Application Priority Data
Dec. 13, 2004 (DE) 102004059917.3

(51) Int. Cl. G01R 31/04

(52) U.S. Cl. 324/538

(57) ABSTRACT

A diagnostic resistor via which a diagnostic current flows is used in a diagnostic system for monitoring a connector in particular for high-frequency modules. The diagnostic resistor is integrated into a connector.

The present invention relates to a diagnostic system for monitoring a connector, for high-frequency modules in particular, in which a diagnostic current, which flows over a diagnostic resistor, is analyzed.

### BACKGROUND INFORMATION

For diagnosing connectors it is known to analyze a diagnostic current which flows via a diagnostic resistor. If the diagnostic current lies in a predefined current window, it is assumed that the connector is working properly. Otherwise an error is signaled. This type of monitoring of connectors is used in particular for passive and active antennas since it is otherwise very difficult to detect whether all connectors between the antenna(s) and the connected high-frequency modules such as diversity analyzing unit, amplifier, tuner, etc., are working accurately. This monitoring is even more important in diversity antenna systems since in this case an antenna, which delivers the strongest high-frequency signal, is possibly not considered only because connectors in its supply feed are not working properly.

### ADVANTAGES OF THE INVENTION

By using the measures cited in claim 1, i.e., the diagnostic resistor is integrated into an at least two-pole connector, the space on the product PCB (printed circuit board) for the diagnostic resistor, as well as the deterioration of the product performance due to the diagnostic resistor and the diagnostic current, which may have a detrimental effect on other modules, are omitted. Therefore, the size of the PCB may be reduced or additional product functions may be incorporated in the PCB. Using the measures according to the present invention, a PCB or a mounting plate may be omitted altogether in the case of a passive antenna, since the connector including the integrated diagnostic resistor may be connected to the antenna base directly or via a lead cable without interconnection of a PCB or a mounting plate.

The present invention is suitable for monitoring and analyzing the functionality and the plug-in process of cable connectors in automotive engineering, in particular where other methods are too complex, e.g., in cables such as antenna feeding cables carrying high-frequency signals.

Advantageous embodiments are cited in the subclaims.

### DRAWING

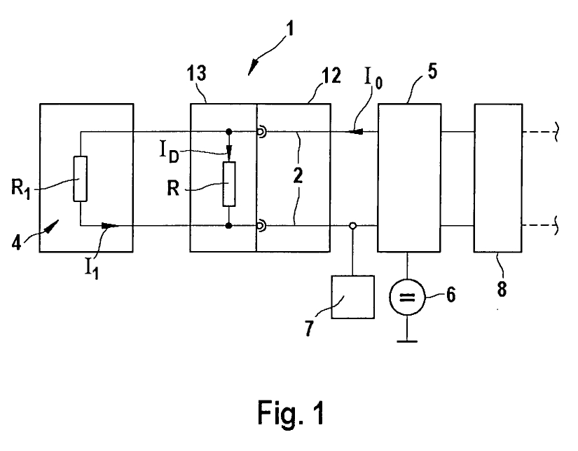

The present invention is explained in greater detail on the basis of FIG. 1 which shows a block diagram including a connector and diagnostic resistor.

### DETAILED DESCRIPTION OF THE EXEMPLARY EMBODIMENTS

FIG. 1 shows a connector 1 whose male plug 12 is connected to a high-frequency module 3, e.g., a high-frequency amplifier, via a wiring harness 2, and whose male plug 13 is connected to a consumer 4, e.g., an active antenna, symbolized by its resistor R1. The high-frequency signal of the consumer, i.e., the antenna, reaches high-frequency amplifier 3 when connector 1 is intact. A feed current I0 which is used as a supply current for an active module of consumer 4, e.g., an active antenna, is applied to wire harness 2 via a phantom feed circuit 5 which is supplied by a direct voltage source 6. In a passive antenna having a high internal resistance or a rod antenna insolated against ground, resistor R1 is highly resistive and portion I1 of current I0, which flows via the antenna, is almost zero. Virtually only a diagnostic current I_{D}, derived from feed current I0, flows via diagnostic resistor 6 integrated into connector 1, the diagnostic resistor being situated between those plug contacts (male plug 13) which lead to the consumer, i.e., to antenna 4. This diagnostic current I_{D} is analyzed in a diagnostic device 7 to determine whether it lies within a predefined current window. If this is the case, it is assumed that connector 1 is intact with regard to the two connector poles and the antenna is properly connected to the connected high-frequency module 8. A diagnostic resistor, which is situated on a PCB of the consumer, may be omitted, as explained above, or the complete PCB may be omitted in a passive antenna in particular.

In order to ensure reliable analysis of diagnostic current I_{D} in a passive antenna, diagnostic resistor 6 is selected to be much smaller than antenna resistor R1. In the case of an active antenna, the diagnostic resistor must be dimensioned in such a way that reliable analysis is possible but that not too much feed power is withdrawn from the active antenna.

Multiple antenna feeds and their connectors may be monitored by one phantom feed circuit when used in a diversity system. It is also possible to monitor multiple connectors between the antenna and high-frequency modules connected in series, e.g., diversity analyzing unit, amplifier, tuner, etc. using one diagnostic resistor.

1-8. (canceled)

9. A diagnostic system for monitoring at least one connector, comprising:
a diagnostic resistor integrated into an at least two-pole connector; and
an arrangement for analyzing a diagnostic current which flows via the diagnostic resistor.

10. The diagnostic system according to claim 9, wherein the diagnostic system is for monitoring at least one connector for a high-frequency module.

11. The diagnostic system according to claim 9, wherein the connector including the integrated diagnostic resistor is situated in a signal path between an antenna and a high-frequency module.

12. The diagnostic system according to claim 9, wherein the diagnostic current is fed toward one of a consumer and an antenna.

13. The diagnostic system according to claim 12, wherein the diagnostic resistor is situated between plug contacts of the connector which lead to the one of the consumer and the antenna.

14. The diagnostic system according to claim 9, wherein the diagnostic current is phantom-fed.

15. The diagnostic system according to claim 11, wherein the connector is directly connected to an antenna base of the antenna, without an interconnection of a PCB or a mounting plate.

16. The diagnostic system according to claim 9, wherein the diagnostic resistor is substantially smaller than a resistor of one of a connected consumer and an antenna.

17. The diagnostic system according to claim 9, wherein the diagnostic current is derived from a feed current of an active circuit, including an active antenna.
